(19) United States
(12) Patent Application Publication
(10) Pub. No.: US 2015/0170879 A1
(43) Pub. Date: Jun. 18, 2015

(54) SEMICONDUCTOR SYSTEM ASSEMBLIES AND METHODS OF OPERATION

(71) Applicant: Applied Materials, Inc., Santa Clara, CA (US)

(72) Inventors: Andrew Nguyen, San Jose, CA (US); Kartik Ramaswamy, San Jose, CA (US); Srinivas Nemani, Sunnyvale, CA (US); Bradley Howard, Pleasanton, CA (US); Yogananda Sarode Vishwanath, Karnataka (IN)

(73) Assignee: Applied Materials, Inc., Santa Clara, CA (US)

(21) Appl. No.: 14/108,683

(22) Filed: Dec. 17, 2013

(51) Int. Cl. H01J 37/32

(52) U.S. Cl. CPC H01J 37/32082

(57) ABSTRACT

An exemplary semiconductor processing system may include a high-frequency electrical source that has an outlet plug. The system may include a processing chamber having a top plate, and an inlet assembly coupled with the top plate. The inlet assembly may include an electrode defining an aperture at a first end and configured to receive the outlet plug. The aperture may be characterized at the first end by a first diameter, and a second end of the aperture opposite the first end may be characterized by a second diameter less than the first diameter. The inlet assembly may further include an inlet insulator coupled with the top plate and configured to electrically insulate the top plate from the electrode.

### CROSS-REFERENCES TO RELATED APPLICATIONS

This Application is related to U.S. application Ser. No. ______ (Attorney Docket No. 80042-894190 (114801US)) entitled “SEMICONDUCTOR SYSTEM ASSEMBLIES AND METHODS OF OPERATION,” and U.S. application Ser. No. ______ (Attorney Docket No. 80042-894191 (114802US)) entitled “SEMICONDUCTOR SYSTEM ASSEMBLIES AND METHODS OF OPERATION,” all of which were filed concurrently on Dec. 17, 2013, the entire disclosures of which are hereby incorporated by reference for all purposes.

### TECHNICAL FIELD

The present technology relates to semiconductor systems, processes, and equipment. More specifically, the present technology relates to systems and methods for reducing film contamination and equipment degradation.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Systems, chambers, and processes are provided for controlling chamber degradation due to high voltage plasma. The systems may provide configurations for components that allow improved plasma profiles to be delivered. The chambers may include modified components less likely to degrade due to exposure to plasma. The methods may provide for the limiting or prevention of chamber or component degradation as a result of etching processes performed by system tools.

Exemplary semiconductor processing systems may include a high-frequency electrical source including an outlet plug as well as a processing chamber having a top plate. The processing systems may further include an inlet assembly coupled with the top plate and including an electrode defining an aperture at a first end. The electrode may be configured to receive the outlet plug, and the aperture may be characterized at the first end by a first diameter, and a second end of the aperture opposite the first end may be characterized by a second diameter less than the first diameter. The semiconductor processing systems may further include an inlet insulator coupled with the top plate and configured to electrically insulate the top plate from the electrode.

Exemplary inlet insulators may define an insulator opening, and the semiconductor processing system may further include a nozzle positioned at least partially within the insulator opening. In embodiments, the nozzle may define a channel extending through the nozzle. The semiconductor processing systems may further include an ignition rod having a first surface. The ignition rod may be positioned between the electrode and the nozzle, and at least a portion of the ignition rod may extend into the channel defined by the nozzle. The ignition rod may define an ignition opening extending into the first surface, and may further define a ledge within the ignition opening. In embodiments, the electrode may be located at least partially within the ignition opening and seated on the ledge.

The semiconductor processing systems may further include an RF insulator coupled with the first surface of the ignition rod. At least a portion of the electrode may extend above the RF insulator in disclosed embodiments. Exemplary processing systems may further include a showerhead, and in disclosed embodiments at least a portion of the showerhead may be silicon. In disclosed embodiments at least a portion of the showerhead may be coated with a treatment material, and the treatment material may be selected from the group consisting of silicon and a ceramic. The high-frequency electrical source utilized in the semiconductor processing systems may be configured to operate at a frequency of at least about 13.56 MHz, and in disclosed embodiments may be configured to operate at a frequency of at least about 60 MHz.

Semiconductor processing systems are also described and may include a processing chamber having a top plate and a high-frequency electrical source. The systems may include an electrode positioned between the processing chamber and the high-frequency electrical source, and may also include an ignition rod at least partially housing the electrode. An RF insulator may be positioned between the ignition rod and the high-frequency electrical source, and the systems may also include a nozzle defining an aperture through which at least a portion of the ignition rod extends. The semiconductor processing systems may also include an inlet insulator housing the nozzle that may be coupled with the top plate to electrically insulate the top plate from the electrode. An RF shield may also be included that encompasses at least a portion of the ignition rod, the nozzle, and the inlet insulator. The semiconductor processing systems may further include a gas distribution baffle, and may also include a showerhead in disclosed embodiments.

Etching methods are also described that may include striking a plasma with a high-frequency electrical source. The plasma may be used in the methods to create a flux of nonreactive ions that may be delivered to a semiconductor processing chamber housing a substrate. The ions may be utilized to etch materials on a substrate in disclosed embodiments. Such methods may allow for reduced component bombardment within the semiconductor processing system which may reduce sputtering of system components. By reducing contamination from such sputtered particles, overall device quality may be improved along with reduced wear or degradation of system components.

Such technology may provide numerous benefits over conventional systems and techniques. For example, degradation of the electrode and other chamber components may be prevented or limited. An additional advantage is that improved etching profiles may be provided based on improved plasma control over a broader frequency range. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to the present technology.

FIG. 2 shows a schematic cross-sectional view of an exemplary processing chamber according to the present technology.

FIG. 3 shows a schematic cross-sectional view of a portion of an exemplary processing system according to the disclosed technology.

FIG. 4 shows a schematic cross-sectional view of a portion of an exemplary processing chamber according to the disclosed technology.

FIG. 5 shows a method of etching that may reduce film contamination according to the present technology.

Several of the Figures are included as schematics. It is to be understood that the Figures are for illustrative purposes, and are not to be considered of scale unless specifically stated to be as such.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing. When plasmas are formed in situ in processing chambers, such as with a capacitively coupled plasma (“CCP”) for example, exposed surfaces of the chamber may be sputtered or degraded by the plasma or the species produced by the plasma. This may in part be caused by bombardment to the surfaces or surface coatings by generated plasma particles. The extent of the bombardment may itself be related to the voltage utilized in generating the plasma. For example, higher voltage may cause higher bombardment, and further degradation.

Conventional technologies have often dealt with this degradation by providing replaceable components within the chamber. Accordingly, when coatings or components themselves are degraded, the component may be removed and replaced with a new component that will in turn degrade over time. However, based on the relationship of voltage to bombardment the present systems may at least partially overcome or reduce this need to replace components by utilizing low-voltage, high-frequency, plasma generation. By utilizing high-frequency electrical sources, multiple benefits or advantages may be provided. For example, the electrode used in plasma generation, as well as coatings to the electrode, may have reduced corrosion due to bombardment because of the lower system voltage based on the V/Hz relationship if peak voltage is not adjusted at varying frequency. Additionally, utilizing high-frequency sources that allow adjustment to the frequency may provide improved plasma control over a broader frequency range. Accordingly, the systems described herein provide improved performance and cost benefits over many conventional designs. These and other benefits will be described in detail below.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

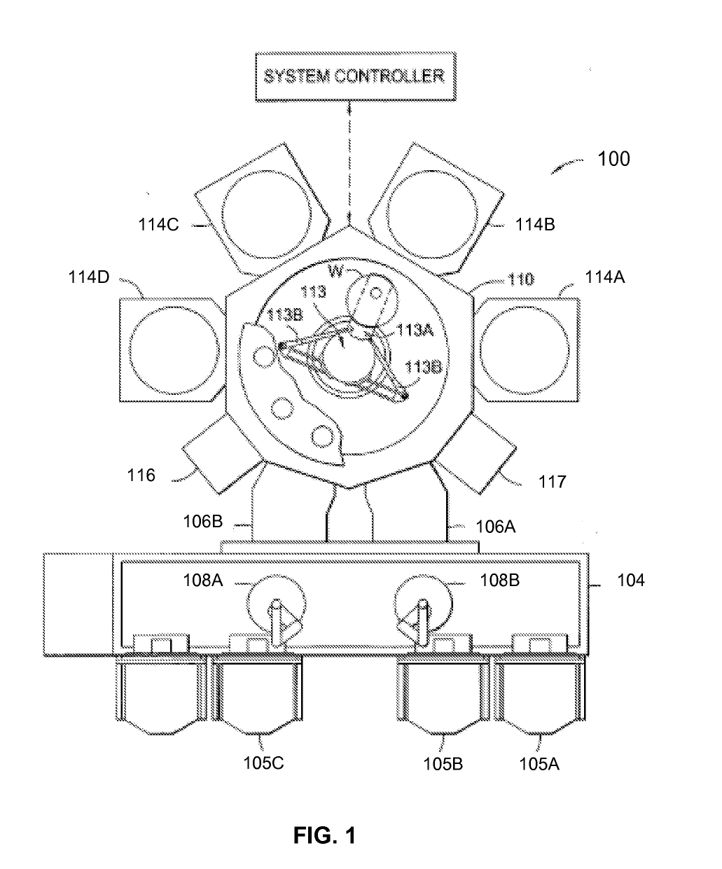

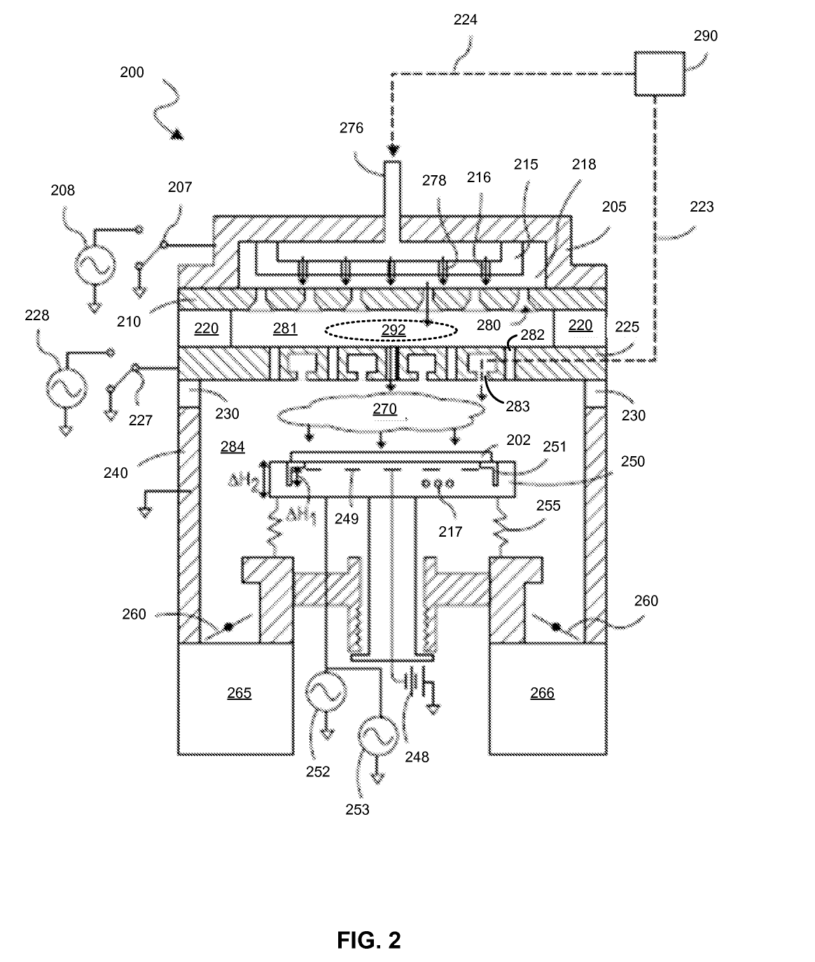

FIG. 1 shows a top plan view of one embodiment of a processing system 100 of deposition, etching, baking, and curing chambers according to embodiments. The processing tool 100 depicted in FIG. 1 may contain a plurality of process chambers, 114A-D, a transfer chamber 110, a service chamber 116, an integrated metrology chamber 117, and a pair of load lock chambers 106A-B. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113A attached to the distal ends of extendible arms 113B, respectively. The blades 113A may be used for carrying individual substrates to and from the process chambers. In operation, one of the substrate transport blades such as blade 113A of the transport mechanism 113 may retrieve a substrate W from one of the load lock chambers such as chambers 106A-B and carry substrate W to a first stage of processing, for example, an etching process as described below in chambers 114A-D. If the chamber is occupied, the robot may wait until the processing is complete and then remove the processed substrate from the chamber with one blade 113A and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106A-B. From the load lock chambers 106A-B, the substrate may move into a factory interface 104. The factory interface 104 generally may operate to transfer substrates between pod loaders 105A-D in an atmospheric pressure clean environment and the load lock chambers 106A-B. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108A-B, may be positioned in factory interface 104 to transport substrates between various positions/locations within factory interface 104 and to other locations in communication therewith. Robots 108A-B may be configured to travel along a track system within enclosure 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed Generally, the etch chamber 200 may include a first capacitively-coupled plasma source to implement an ion milling operation and a second capacitively-coupled plasma source to implement an etching operation and to implement an optional deposition operation. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller (not shown). In disclosed embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, Argon delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer.

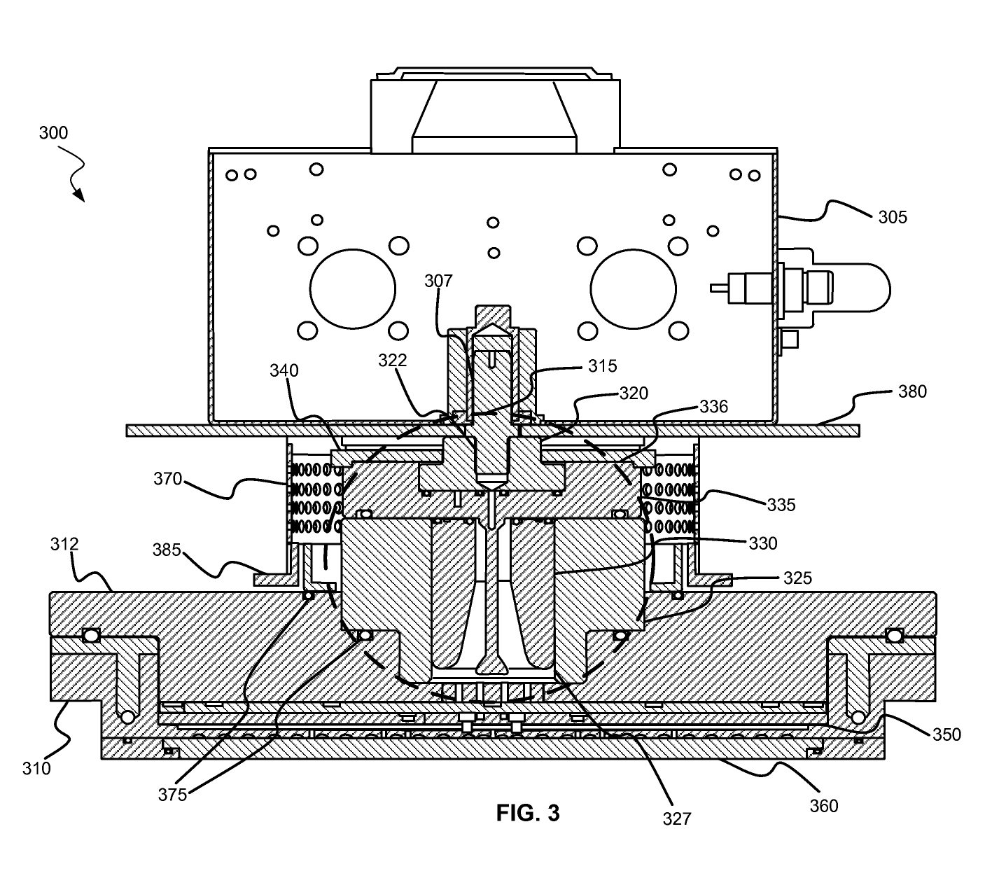

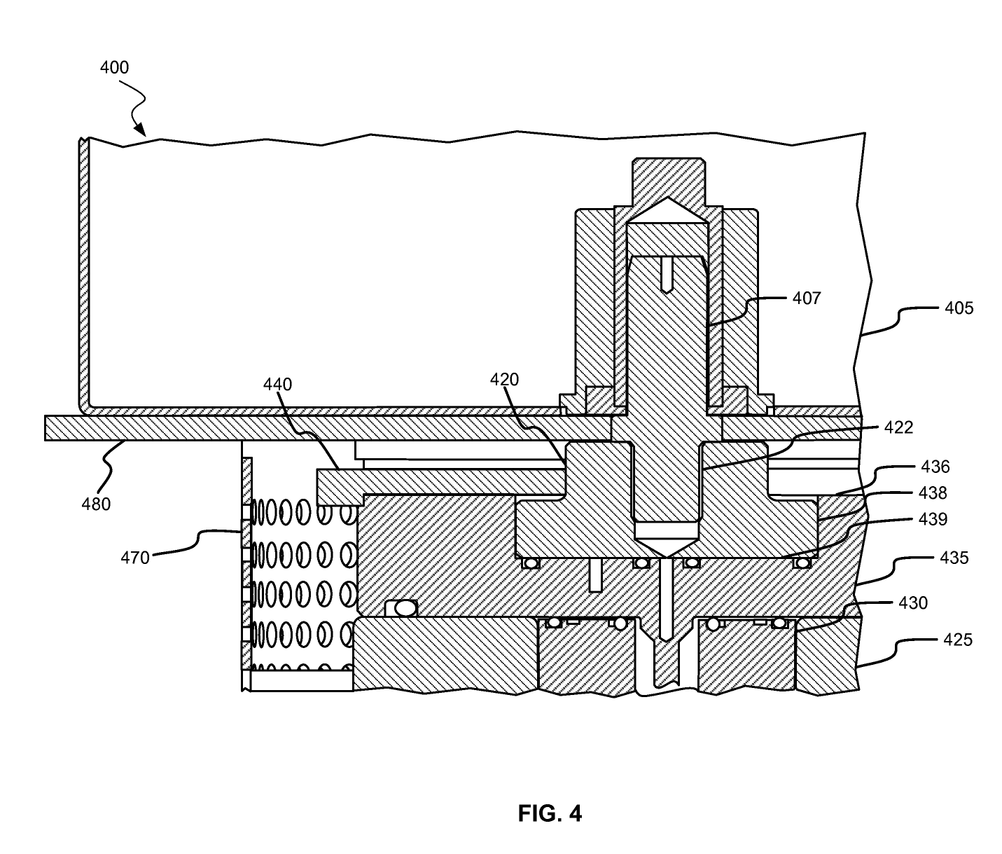

FIG. 3 shows a schematic cross-sectional view of a portion of an exemplary processing system 300 according to the disclosed technology. As illustrated, system 300 includes a more detailed view of an exemplary version of a top portion and related components of, for example, system 200 as previously described. Semiconductor processing system 300 may include a high-frequency electrical source 305 that includes an outlet plug 307. Via an inlet gas assembly, the multiple components of which are identified as 315, electrical source 305 may be coupled with a processing chamber 310 including top plate 312, which may be similar in aspects to top cover 205 as previously described. Inlet gas assembly 315 may include a number of components utilized in generating the plasma and delivering precursors into chamber 310. The inlet gas assembly may be coupled with the top plate 312 via an insulator 325 that may be configured to electrically insulate the top plate 312 from the electrode 320. Electrode 320 may define an aperture 322 that, at a first end, may be configured to receive outlet plug 307 of electrical source 305. Electrode 320 may be made of a variety of conductive materials and metals, and in embodiments may include coatings, such as metal coatings including transition metals, including nickel, for example. As will be explained in greater detail with reference to FIG. 4, aperture 322 may be characterized at the first end by a first diameter, and a second end of the aperture 322 opposite the first end may be characterized by a second diameter less than the first diameter.

Inlet insulator 325 may define an insulator opening 327 in which may be positioned a nozzle 330 configured to deliver precursors for plasma processing. As illustrated in the figure, nozzle 330 may define a channel extending through the device, which may be configured to affect the flow of precursors being delivered. For example, embodiments may include a cylindrical portion of nozzle 330 extending to a conical portion of nozzle 330 which may increase radially towards processing chamber 310. Such a configuration may affect the precursor distribution in plasma generation, which may aid uniformity of the plasma within the processing chamber 310. System 300 may further include an ignition rod 335 as part of the inlet assembly 315. Ignition rod 335 may be positioned between the electrode 320 and the nozzle 330, and at least a portion of the ignition rod 335 may extend into the channel defined by the nozzle 330.

Ignition rod 335 may include a first surface 336 in which an ignition opening may be defined that extends into the first surface 336. A ledge may be defined within the ignition opening, and electrode 320 may be located at least partially within the ignition opening and be seated on this ledge. Processing system 300 may further include an RF insulator 340 positioned between the high-frequency electrical source 305 and ignition rod 335, which may operate to further electrically isolate the components of the inlet assembly 315. Both RF insulator 340 and inlet insulator 325 may be composed of a variety of dielectric or other insulating materials including ceramic in disclosed embodiments. As illustrated in the figure, RF insulator 340 may be coupled with the first surface of the ignition rod 335. In embodiments, at least a portion of electrode 320 may extend above the RF insulator 340 coupling with the outlet plug 307 of the electrical source 305. RF shielding 370 may additionally be included to encompass at least a portion of the ignition rod 335, the nozzle 330, and the inlet insulator 325. RF shielding 370 may also operate as an RF return in disclosed embodiments.

Semiconductor processing system 300 may include additional components within the chamber 310, including a gas distribution baffle 350 and a showerhead 360. In embodiments, showerhead 360 may include silicon as part or all of the composition. For example, showerhead 360 may be a one-piece design that is substantially composed of silicon. In additional embodiments, showerhead 360 may be a multi-piece design in which one or more of the pieces include silicon as part or all of the composition. For example, in a two-piece coupled design, the showerhead section closer to the substrate or workpiece may be made of silicon, while the showerhead section further from the substrate or workpiece may be metal. In other multi-piece designs, one or more of the pieces may be of an insulating material while one or more of the other pieces may be of a conductive material. In this way, showerhead 360 may still be used as an electrode during plasma generation in various areas of the chamber 310. In disclosed embodiments, at least a portion of showerhead 360 may be coated with a treatment material, which may include a variety of insulating materials including silicon and ceramics, for example.

High-frequency electrical source 305 may operate at any number of frequencies useful for producing plasma, including variable frequencies, and in embodiments may be configured to provide high-frequency, low-voltage electrical power. Thus, in disclosed embodiments, the high-frequency electrical source 305 may be configured to operate at frequencies of up to or at least 10 MHz. Additionally, the high-frequency electrical source may be configured to operate at frequencies of at least, up to, or about 13 or 13.56 MHz, 40 MHz, 60 MHz, 100 MHz, 400 MHz, 1000 MHz, 2450 MHz, etc., or more. However, such electrical sources may include much larger outlet plugs 307 requiring specialized inlet assembly 315 components in order to couple the power supplies.

Many conventional power supplies utilized in plasma generation may provide power down below 100 kHz, 10 kHz, or less. Such power supplies often have small outlet plugs to be coupled with a processing chamber. Accordingly, common inlet assembly arrangements may be designed to couple with such power supplies. Modifying the system to accommodate a high-frequency electrical power supply may require significant modifications to the inlet assembly to accommodate not only larger outlet plug sizes, but also the increased weight of the power supply itself. Embodiments of the present technology may be specifically configured to accommodate such high-frequency power supplies as will be described in detail herein.

In order to accommodate the increased size and weight of the high-frequency electrical source 305, a mounting plate 380 may be positioned above RF insulator 340 in order to properly balance and support the power supply 305. Electrode 320 may include a portion extending to receive the outlet plug 307, and this portion may be of an increased size or diameter, such as of a diameter greater than the thickness of the electrode in order to support additional strain from the electrical source 305 and help reduce the chance of sheer or deformation of electrode 320. Semiconductor processing system 300 may additionally include floating supports 385 that may provide further support during operation. Processing system 300 may include one or more o-rings 375 which may aid in reducing leakage during operation, which may occur under vacuum conditions. Compression of o-rings 375 may occur both from vacuum conditions as well as from the weight of high-frequency electrical source 305. In such case, o-rings 375 may compress to an extent to allow floating legs 385 to engage top plate 312 with chamber 310. Floating legs 385 may then in turn reduce strain on inlet assembly 315 components as well as aid in reducing vibration during operation.

Turning to FIG. 4, shown is a schematic cross-sectional view of a portion of an exemplary processing chamber 400 according to the disclosed technology, which includes a detailed view of inlet assembly 315 previously described. Accordingly, semiconductor processing chamber 400 may include similar components as chamber 300 including a processing chamber having a top plate with which the illustrated structures are coupled. Semiconductor processing system 400 may include a high-frequency electrical source 405 including an outlet plug 407 seated on mounting plate 480, as well as electrode 420 positioned between the processing chamber (not shown) and the high-frequency electrical source 405. Semiconductor processing system 400 may further include an ignition rod 435 at least partially housing the electrode 420 as well as an RF insulator 440 positioned between the ignition rod 435 and the high-frequency electrical source 405. The system may further include a nozzle 430 defining an aperture through which at least a portion of the ignition rod 435 extends. In embodiments, the system may include an inlet insulator 425 housing the nozzle 430 and coupled with the top plate (not shown) to electrically insulate the top plate from the electrode 420. An RF shield 470 may be configured to operate as an RF return and may additionally encompass at least a portion of the ignition rod 435, the nozzle 430, and the inlet insulator 425.

As previously described but illustrated in the figure in greater detail, ignition rod 435 may include a first surface 436, which faces the electrical source 405. Ignition rod 435 may further define an ignition opening 438 that may define a ledge or bottom of the ignition opening 439. Electrode 420 may be located at least partially within opening 438 and be seated on the ledge 439 of the ignition rod 435. At least a portion of electrode 420 may extend beyond first surface 436 of ignition rod 435 as well as beyond RF insulator 440 towards electrical source 405. The portion of electrode 420 extending beyond ignition rod 435 may be of a width or diameter that may be equal to or greater than the overall thickness of electrode 420, which may reduce or better accommodate strain imposed by electrical source 405. Electrode 420 may define an aperture 422 characterized by a first end proximate electrical source 405 and a second end opposite the first end. In disclosed embodiments, aperture 422 may not fully extend through electrode 420. The first end of aperture 422 may be characterized by a first diameter, and the second end of the aperture 422 may be characterized by a second diameter less than the first diameter in disclosed embodiments.

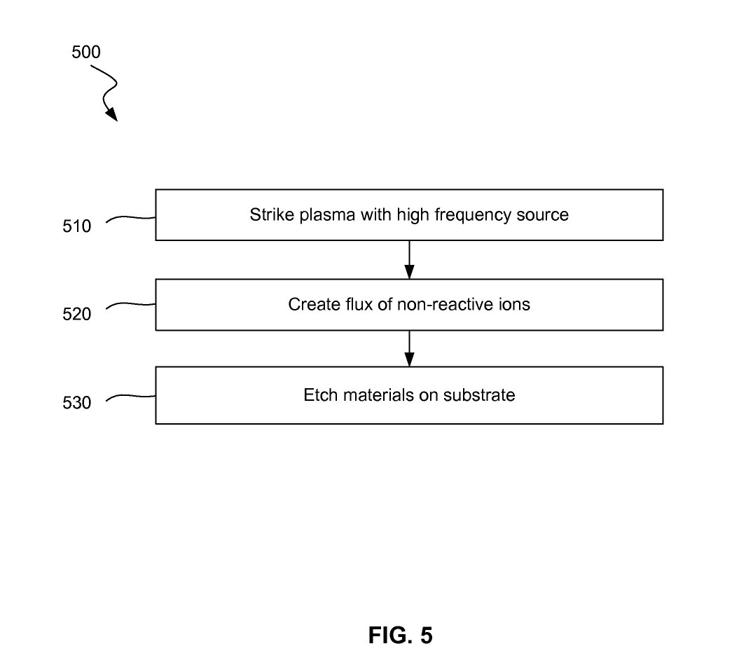

FIG. 5 shows a method 500 of etching that may reduce film contamination according to the present technology. Method 500 may be performed in any of the systems previously described and may include optional operations including delivering a precursor for ionization to the system. Method 500 may include striking a plasma with a high-frequency electrical source in operation 510, which may include an operating frequency previously described, and in one embodiment may be at least 60 MHz. The method may include creating a flux of nonreactive ions in operation 520 such as from an ionization of the precursor being delivered which may include one or more precursors that may include argon, helium, hydrogen, nitrogen, and additional inert or reactive precursors.

The flux of nonreactive ions may be characterized by reduced bombardment of the system components based on the high-frequency electrical source utilized to produce the plasma. The flux of nonreactive ions may be delivered to a substrate housed in a processing chamber, and then may etch the substrate or materials on the substrate, such as with ion milling at operation 530. By reducing system and chamber component bombardment, sputtering of chamber components or coatings, such as an electrode coating, may be reduced or prevented in embodiments. The sputtered particles may be carried through the system and deposited on the substrate being worked, which may result in short-circuiting or failure of the produced device. Accordingly, by utilizing the described methods increased device quality may be provided as well as increased chamber component life.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system comprising:
a high-frequency electrical source including an outlet plug;
a processing chamber having a top plate; and
an inlet assembly coupled with the top plate and comprising:
an electrode defining an aperture at a first end and configured to receive the outlet plug, wherein the aperture is characterized at the first end by a first diameter, and wherein a second end of the aperture opposite the first end is characterized by a second diameter less than the first diameter, and
an inlet insulator coupled with the top plate and configured to electrically insulate the top plate from the electrode.

2. The semiconductor processing system of claim 1, wherein the inlet insulator defines an insulator opening, wherein the semiconductor processing system further comprises a nozzle positioned at least partially within the insulator opening, and wherein the nozzle defines a channel extending through the nozzle.

3. The semiconductor processing system of claim 1, wherein the semiconductor processing system further comprises an ignition rod having a first surface, wherein the ignition rod is positioned between the electrode and the nozzle, and wherein at least a portion of the ignition rod extends into the channel defined by the nozzle.

4. The semiconductor processing system of claim 3, wherein the ignition rod defines an ignition opening extending into the first surface, wherein the ignition rod defines a ledge within the ignition opening, and wherein the electrode is located at least partially within the ignition opening and seated on the ledge.

5. The semiconductor processing system of claim 3, wherein the semiconductor processing system further comprises an RF insulator coupled with the first surface of the ignition rod.

6. The semiconductor processing system of claim 5, wherein at least a portion of the electrode extends above the RF insulator.

7. The semiconductor processing system of claim 1, wherein the semiconductor processing system further comprises a showerhead.

8. The semiconductor processing system of claim 7, wherein at least a portion of the showerhead is silicon.

9. The semiconductor processing system of claim 7, wherein at least a portion of the showerhead is coated with a treatment material.

10. The semiconductor processing system of claim 9, wherein the treatment material is selected from the group consisting of silicon and a ceramic.

11. The semiconductor processing system of claim 1, wherein the high-frequency electrical source is configured to operate at a frequency of at least about 13.56 MHz.

12. The semiconductor processing system of claim 11, wherein the high-frequency electrical source is configured to operate at a frequency of at least about 60 MHz.

13. A semiconductor processing system comprising:
a processing chamber having a top plate;
a high-frequency electrical source;
an electrode positioned between the processing chamber and the high-frequency electrical source;
an ignition rod at least partially housing the electrode;
an RF insulator positioned between the ignition rod and the high-frequency electrical source;
a nozzle defining an aperture through which at least a portion of the ignition rod extends;
an inlet insulator housing the nozzle, and coupled with the top plate to electrically insulate the top plate from the electrode; and
an RF shield encompassing at least a portion of the ignition rod, the nozzle, and the inlet insulator.

14. The semiconductor processing system of claim 13, further comprising a gas distribution baffle and a showerhead.

15. An etching method, the method comprising:
striking a plasma with a high-frequency electrical source;
creating a flux of non-reactive ions;
delivering the ions to a substrate; and
etching materials on the substrate.
